(19) United States
(12) Patent Application Publication
(10) Pub. No.: US 2025/0386479 A1
(43) Pub. Date: Dec. 18, 2025

(54) SEMICONDUCTOR STRUCTURE AND MANUFACTURING METHOD THEREOF

(71) Applicant: TAIWAN SEMICONDUCTOR MANUFACTURING COMPANY LTD., HSINCHU (TW)

(72) Inventors: CHUN-HAO CHU, HSINCHU CITY (TW); YOU-CHENG XIAO, TAICHUNG CITY (TW); POCHUN WANG, HSINCHU (TW); YU-HAN LIU, TAOYUAN CITY (TW); PIN-DAI SUE, TAINAN CITY (TW)

(21) Appl. No.: 18/744,744

(22) Filed: Jun. 17, 2024

(51) Int. Cl. H10B 10/00; H01L 27/118; H03K 19/20

(52) U.S. Cl. CPC H10B 10/125; H10D 84/907; H03K 19/20; H10D 84/953; H10D 84/981

(57) ABSTRACT

A semiconductor structure is provided. The semiconductor structure includes a plurality of transistors formed in an active region of a device layer, a first power line disposed on a front side of the device layer and extending in a first direction, a first connecting feature disposed on a source/drain region of the transistors and extending in a second direction perpendicular to the first direction, a second power line disposed on a back side of the device layer and extending in the first direction, and a feedthrough via formed on and in contact with the second power line. The active region extending in the first direction and the feedthrough via are disposed on two opposite sides of the first power line from a top view. The second power line is electrically connected to the source/drain region of the transistors through the feedthrough via and the first connecting feature.

### BACKGROUND

As integrated circuit (IC) technologies progress towards smaller technology nodes, some routing structures have been moved from the front side of the semiconductor structure to the backside of the semiconductor structure in an IC. For example, backside power rails (BPR) or super power rails (SPR) have been proposed where a backside source/drain contact is formed through the semiconductor substrate to come in contact with a source/drain feature and a power line is formed on the backside of the semiconductor substrate to be in contact with the backside source/drain contact.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a block diagram of an exemplary SRAM device, in accordance with some embodiments of the disclosure.

FIG. 2 is a cross section of a semiconductor structure of the SRAM device of FIG. 1, in accordance with some embodiments of the disclosure.

FIG. 3 illustrates an exemplary layout of a semiconductor structure without enhancement interconnects for a power mesh, in accordance with some embodiments of the disclosure.

FIGS. 4A and 4B are cross sections of the semiconductor structure along a line A-A′ and a line B-B′ in FIG. 3, respectively, in accordance with some embodiments of the disclosure.

FIG. 5 illustrates an exemplary layout of a semiconductor structure with enhancement interconnects for a power mesh, in accordance with some embodiments of the disclosure.

FIGS. 6A and 6B are cross sections of the semiconductor structure along a line A-A′ and a line B-B′ in FIG. 5, respectively, in accordance with some embodiments of the disclosure.

FIG. 7 illustrates an exemplary layout of a semiconductor structure without enhancement interconnects for a power mesh, in accordance with some embodiments of the disclosure.

FIGS. 8A and 8B are cross sections of the semiconductor structure along a line A-A′ and a line B-B′ in FIG. 7, respectively, in accordance with some embodiments of the disclosure.

FIG. 9 illustrates an exemplary layout of a semiconductor structure with enhancement interconnects for a power mesh, in accordance with some embodiments of the disclosure.

FIGS. 10A through 10D are cross sections of the semiconductor structure along the lines A-A′, B-B′, C-C′ and D-D′ in FIG. 9, respectively, in accordance with some embodiments of the disclosure.

FIG. 11 illustrates an exemplary layout of a semiconductor structure with enhancement interconnects for a power mesh, in accordance with some embodiments of the disclosure.

FIG. 12 is a cross section of the semiconductor structure along the lines A-A′ in FIG. 11, in accordance with some embodiments of the disclosure.

FIG. 13 is a circuit diagram of a logic cell, in accordance with some embodiments of the disclosure.

FIG. 14 illustrates an exemplary layout of a semiconductor structure of the logic cell in FIG. 13, in accordance with some embodiments of the disclosure.

FIG. 15 illustrates an exemplary layout of a semiconductor structure with enhancement interconnects for VSS mesh, in accordance with some embodiments of the disclosure.

FIG. 16 shows a method for manufacturing a semiconductor structure, in accordance with some embodiments of the disclosure.

### DETAILED DESCRIPTION

The following disclosure provides many different embodiments, or examples, for implementing different features of the provided subject matter. Specific examples of components and arrangements are described to simplify the disclosure. These are, of course, merely examples and are not intended to be limiting. For example, the formation of a first feature over or on a second feature in the description that follows may include embodiments in which the first and second features are formed in direct contact, and may also include embodiments in which additional features may be formed therebetween. In addition, the present disclosure may repeat reference numerals and/or letters in the various examples. This repetition is for the purpose of simplicity and clarity and does not in itself dictate a relationship between the various embodiments and/or configurations discussed.

While embodiments of the present disclosure are discussed in detail, it should be appreciated that the present disclosure provides many applicable inventive concepts that can be embodied in a wide variety of specific contexts. The specific embodiments discussed are merely illustrative and do not limit the scope of the disclosure.

Further, spatially relative terms, such as “beneath,” “below,” “lower,” “above,” “upper,” “lower,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

Various semiconductor structures in integrated circuits (ICs) are provided in accordance with various exemplary embodiments. Some variations of some embodiments are discussed. Throughout the various views and illustrative embodiments, like reference numbers are used to designate like elements.

According to the embodiments of the present disclosure, enhancement interconnects of power mesh are formed in the non-functional active regions. A larger non-functional active region is removed and replaced by a feedthrough via between a backside power line and a front side power line, so as to improve IR performance of a power mesh formed by the backside power line and the front side power line. For a smaller non-functional active region including multiple floating transistors, one or more backside connection features are formed between the source/drain regions of floating transistors and a backside power line, so as to provide more parallel paths for a power mesh, thereby decreasing IR drop of the power mesh.

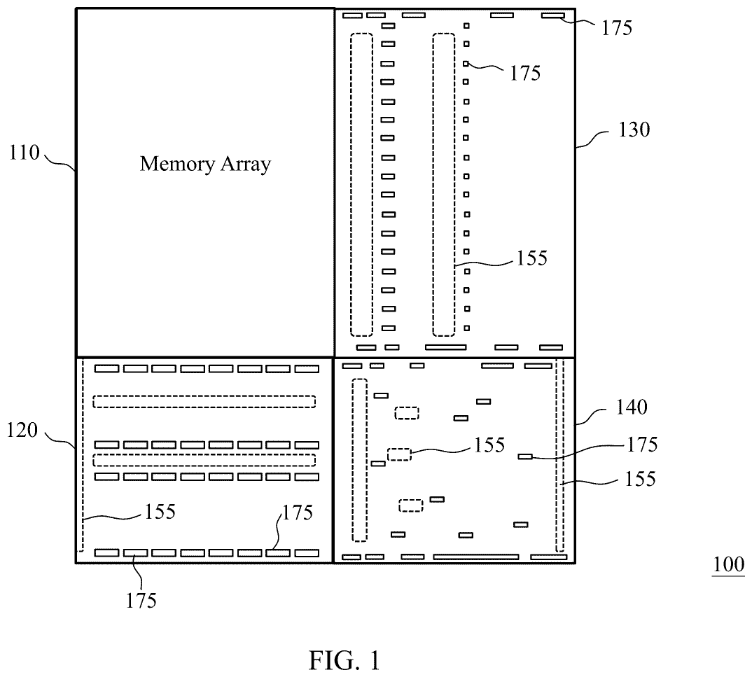

FIG. 1 is a block diagram of an exemplary static random access memory (SRAM) device 100, in accordance with some embodiments of the disclosure. The SRAM device 100 is implemented in an integrated circuit (IC), and can be accessed by a controller. The controller may be implemented in the same IC or another IC.

The SRAM device 100 includes a memory array 110, a word line driver (WLDV) block 120, an input/output (IO) block 130 and a control (CNT) block 140. The memory array 110 includes the memory cells (not shown) arranged in rows and columns of an array, where each memory cell may be a SRAM cell. The CNT block 140 is configured to control the operations of the WLDV block 120 and the IO block 130 in response to the address and command from the controller, so as to access the memory array 110. The WLDV block 120 is configured to control the word lines (WLs) of the memory array 110 during read and write operations. The IO block 130 is configured to provide the writing data to the bit lines (BLs) of the memory array 110 during write operations, and sense the stored data from the bit lines of the memory array 110 during read operations.

In the SRAM device 100, multiple dummy regions 175 and multiple header units 155 are arranged in the WLDV block 120, the IO block 130 and the CNT block 140. The dummy region 175 has a larger area than the header unit 155. Each dummy region 175 includes multiple dummy devices (i.e., non-functional devices), and the dummy devices include the active devices and/or the passive devices. In some embodiments, the dummy devices are used to repair the design of the WLDV block 120, the IO block 130 or the CNT block 140 through back-end-of-line (BEOL) process if necessary. Moreover, each header unit 155 includes a switch (e.g., a P-type transistor) between a power supply line and a functional circuit. Since the transistors are often formed in PN pairs and the P-type transistor is larger than the N-type transistor, the non-functional regions of the dummy regions 175 and the header units 155 can be used to arrange enhancement interconnects (or additional interconnects) between front side power line and backside power line, so as to improve IR performance of the power mesh in the SRAM device 100.

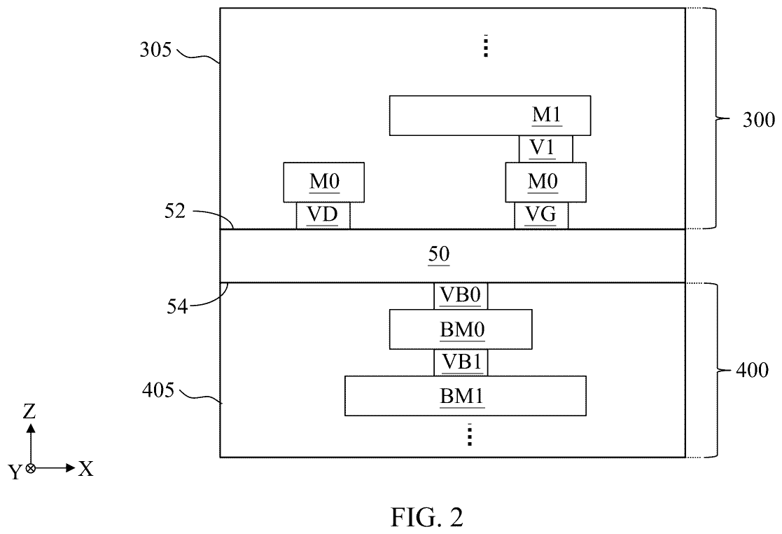

FIG. 2 is a cross section of a semiconductor structure of the SRAM device 100 of FIG. 1, in accordance with some embodiments of the disclosure. The semiconductor structure has a device layer 50 (also referred to as a device region), a front-side interconnect structure 300, and a backside interconnect structure 400. The device layer 50 is where transistors and main features are located, such as the gate, channel, source/drain region, contact features, and the transistors (e.g., the N-type transistors and the P-type transistors). Source/drain region(s) may refer to a source or a drain, individually or collectively, depending on context. The device layer 50 has a front side 52 and a back side 54.

The front-side interconnect structure 300 is formed over the device layer 50 (e.g., at the front side 52 of the device layer 50), and the backside interconnect structure 400 is formed under the device layer 50 (e.g., at the back side 54 of the device layer 50). The front-side interconnect structure 300 includes an inter-metal dielectric (IMD) 305, the front-side connecting features (e.g., the vias VG, VD and V1), and the metal lines M0 and M1. The metal line M0 is formed in the lowest metal layer in the front-side interconnect structure 300, and the lowest metal layer is the metal layer closest to the device layer 50. The backside interconnect structure 400 includes the IMD 405, the backside connecting features (e.g., the vias VB0 and VB1), and the metal lines BM0 and BM1. In the backside interconnect structure 400, the metal line BM0 is formed in the metal layer closest to the device layer 50. The vias and metal lines in the IMD 405 and the IMD 305 are electrically coupled to various transistors and/or components (e.g., the gate, source/drain features, resistors, capacitors, and/or inductors) of the device layer 50, such that the various devices and/or components can operate as specified by design requirements. It should be noted that there may be more vias and metal lines in the IMD 305 and the IMD 405 for connections. The IMD 305 and the IMD 405 may be multilayered.

The backside interconnect structure 400 is at the back side 54 of the device layer 50, and the IMD 405, the vias VB0, VB1, and the metal lines BM0, BM1 may also be referred to as the backside IMD, the backside vias, and the backside metal lines, respectively. Similarly, the front-side interconnect structure 300 is at the front side 52 of the device layer 50, and the IMD 305, the vias VG, VD, V1, and the metal lines M0, M1 may also be referred to as the front-side IMD, the front-side vias, and the front-side metal lines, respectively. In some embodiments, the via VG is connected to the gate structures (gate electrodes) of the transistors, and the via VG is also referred to as the gate via. In some embodiments, the via VD is connected to the source/drain contacts (e.g., source/drain regions) of the transistors.

Formation of the backside interconnect structure 400 may include removing the substrate (if present) by chemical mechanical polishing (CMP), forming a backside dielectric layer (not shown) under the device layer 50, and forming backside contacts or vias (e.g., the via VB0) connected to the source/drain features of the device layer 50. The formation of the front-side interconnect structure 300 is similar to that of the backside interconnect structure 400, the difference being that the formation processes of the front-side interconnect structure 300 are performed at the front side 52 of the device layer 50, and are not described in detail herein.

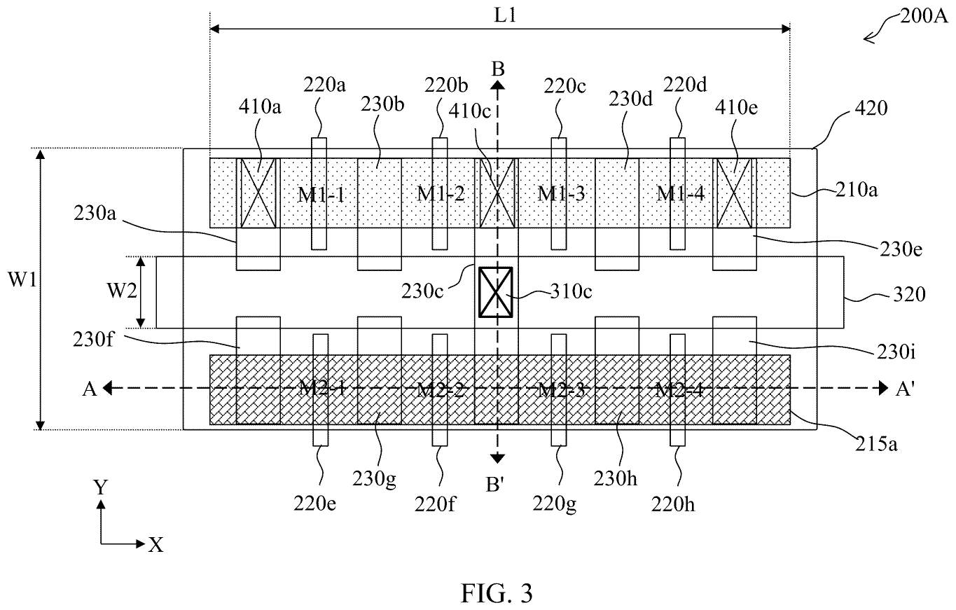

FIG. 3 illustrates an exemplary layout of a semiconductor structure 200A without enhancement interconnects for a power mesh, in accordance with some embodiments of the disclosure. In FIG. 3, the features in the device layer 50 (including transistors), the front-side interconnect structure 300 (including vias and metal lines) and the backside interconnect structure 400 (including vias and metal lines) are shown. The semiconductor structure 200A is formed in the dummy region 175 or the header unit 155 of the WLDV block 120, the IO block 130 or the CNT block 140 in FIG. 1. In some embodiments, the semiconductor structure 200A is formed in a region of the IC other than the SRAM device 100.

The transistors M1-1 through M1-4 are formed in an active region 210a of the device layer 50 of FIG. 2, and the transistors M2-1 through M2-4 are formed in an active region 215a of the device layer 50. The transistors M1-1 through M1-4 are functional devices capable of performing specific functions of a circuit in the IC, and the active region 210a may also be referred to as a functional active region. The transistors M2-1 through M2-4 are the non-functional devices that do not need be arranged to perform specific functions in the circuit, and the active region 215a may also be referred to as a non-functional active region. Furthermore, the transistors M2-1 through M2-4 are dummy transistors floating in the circuit. For example, the gates of the transistors M2-1 through M2-4 are not connected to any metal line.

The active regions 210a and 215a extend along the X-axis and are continuously rectangular in the top view. In some embodiments, the active regions 210a and 215a have the same length L1 along the X-axis. The gate structures 220a through 220d of the transistors M1-1 through M1-4 and the gate structures 220e through 220h of the transistors M2-1 through M2-4 extend along the Y-axis. The gate structures 220a through 220d engage the active region 210a to form the transistors M1-1 through M1-4, and the gate structures 220e through 220h engage the active region 215a to form the transistors M2-1 through M2-4. In order to simplify the description, the connections of the gate structures 220a through 220d of the transistors M1-1 through M1-4 (i.e., the functional transistors) are omitted herefrom. Furthermore, the gate structures 220e through 220h of the transistors M2-1 through M2-4 (i.e., the non-functional transistors) are not connected to other features and other devices because the transistors M2-1 through M2-4 are floating.

The source/drain contacts 230a through 230e extending along the Y-axis are formed on the source/drain regions (or the source/drain features) of the transistors M1-1 through M1-4. The source/drain contact 230b is formed on the common source/drain region of the transistors M1-1 and M1-2, the source/drain contact 230c is formed on the common source/drain region of the transistors M1-2 and M1-3, and the source/drain contact 230d is formed on the common source/drain region of the transistors M1-3 and M1-4. Similarly, the source/drain contact 230g is formed on the common source/drain region of the transistors M2-1 and M2-2, the source/drain contact 230c is formed on the common source/drain region of the transistors M2-2 and M2-3, and the source/drain contact 230h is formed on the common source/drain region of the transistors M2-3 and M2-4.

In FIG. 3, the metal line 320 is formed in the lowest metal layer in the front-side interconnect structure 300 of FIG. 2. Moreover, the metal line 320 is configured to function as a power line (or a power rail), such as a VDD line or a VSS line. In order to simplify the description, the upper level connections of the metal line 320 are omitted. The metal line 320 extends along the X-axis and has a width W2. The metal line 320 is coupled to the source/drain contact 230c through the connecting feature 310c (e.g., the via VD of FIG. 2), so that a source/drain region of each of the transistors M1-2, M1-3, M2-2 and M2-3 is coupled to the metal line 320. From a top view, the active regions 210a and 215a are disposed on two opposite sides of the metal line 320.

In FIG. 3, the metal line 420 is formed in a metal layer of the backside interconnect structure 400 of FIG. 2 closest to the device layer 50. The metal line 420 is configured to function as a power line (or a power rail), such as a VDD line or a VSS line. The metal line 420 extends along the X-axis is of a width W1, which exceeds width W2. In the embodiment, the metal line 420 completely overlaps the active region 210a, the metal line 320 and the active region 215a from a top view. In some embodiments, the metal line 420 partially overlaps the active region 210a, the metal line 320 and the active region 215a. The metal line 420 is coupled to the source/drain regions (not shown) corresponding to the source/drain contacts 230a, 230c and 230e through the connecting features 410a, 410c and 410e (e.g., the via VB0 of FIG. 2), so that the corresponding source/drain region of each of the transistors M1-1 through M1-4 is coupled to the metal line 420. In FIG. 3, the source/drain contacts 230f through 230i are not connected to the metal line 420.

In some embodiments, the transistors M1-1 through M1-4 and the transistors M2-1 through M2-4 are N-type transistors, and the metal lines 320 and 420 are the VSS lines. Furthermore, the connecting features 410a, 410c and 410e are disposed between the source regions of the transistors M1-1 through M1-4 and the metal line 420, i.e., the source/drain regions coupled to the connecting features 410a, 410c and 410e are the source features of the N-type transistors.

In some embodiments, the transistors M1-1 through M1-4 and the transistors M2-1 through M2-4 are P-type transistors, and the metal lines 320 and 420 are the VDD lines. Furthermore, the connecting features 410a, 410c and 410e are disposed between the source regions of the transistors M1-1 through M1-4 and the metal line 420, i.e., the source/drain regions coupled to the connecting features 410a, 410c and 410e are the source features of the P-type transistors.

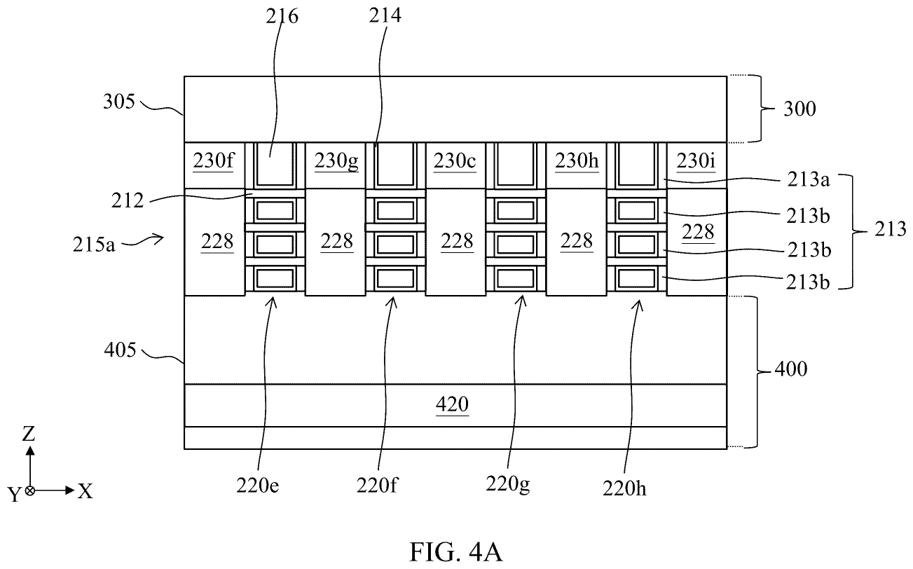

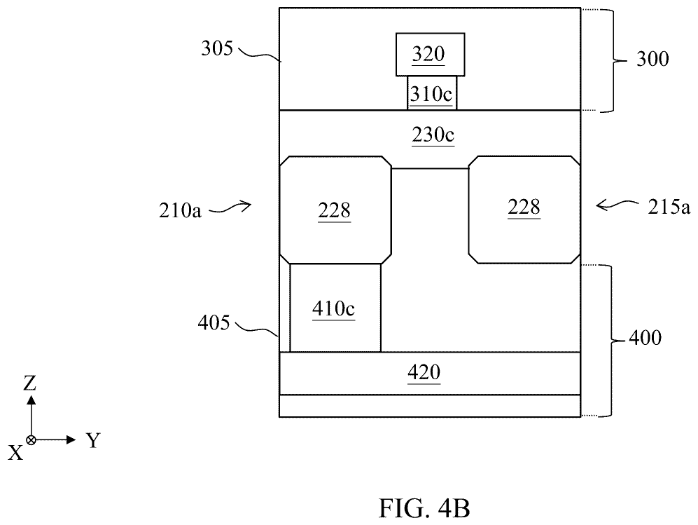

FIG. 4A is a cross section of the semiconductor structure 200A along a line A-A′ in FIG. 3, and FIG. 4B is a cross section of the semiconductor structure 200A along a line B-B′ in FIG. 3, in accordance with some embodiments of the disclosure. In some embodiments, the active region 215a constructed by the nanostructures 212 and the source/drain features 228 remains continuity. More specifically, the nanostructures 212 of the gate structures 220e through 220h, and the source/drain features 228 are connected with each other to construct the continuous active region 215a.

In FIGS. 4A and 4B, the connecting feature 310c and the metal line 320 of the front-side interconnect structure 300 are formed over the active regions 210a and 215a, and the connecting feature 310c and the metal line 320 do not overlap the active regions 210a and 215a. Furthermore, the connecting feature 410c and the metal line 420 of the backside interconnect structure 400 are formed under the active regions 210a and 215a, and the connecting feature 410c overlaps the active region 210a.

Each of gate structures 220e through 220h includes the nanostructures 212 extending along an X-axis and vertically arranged (or stacked) along a Z-axis. More specifically, the nanostructures 212 are spaced from each other along the Z-axis. In some embodiments, the nanostructures 212 may also be referred to as channels, channel layers, nanosheets, or nanowires. The nanostructures 212 may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, the nanostructures 212 include silicon for N-type gate-all-around (GAA) field effect transistors (FETs). In some embodiments, the nanostructures 212 are all made of silicon, and the type of GAA transistors depend on work function metal layer wrapping around the nanostructures 212.

The GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The gate dielectric layer 214 wraps around the nanostructures 212, and the gate electrode 216 wraps around the gate dielectric layer 214. The gate electrode 216 may include polysilicon or work function metal. The work function metal includes TiN, TaN, TiAl, TiAlN, TaAl, TaAlN, TaAlC, TaCN, WNC, Co, Ni, Pt, W, combinations thereof, or other suitable material. The gate dielectric layer 214 may include dielectric materials, such as silicon oxide, silicon nitride, silicon oxynitride, dielectric material(s) with high dielectric constant (high-k), or a combination thereof. Examples of high-k dielectric materials include TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material.

The spacers 213 are on sidewalls of the gate structures 220e through 220h. The spacers 213 include the outer spacers 213a and the inner spacers 213b. The outer spacers 213a are over the nanostructures 212 and on top sidewalls of the gate structures 220e through 220h. The outer spacers 213a may include multiple dielectric materials and be selected from a group consist of SiO₂, Si₃N₄, carbon doped oxide, nitrogen doped oxide, porous oxide, air gap, or, or a combination thereof. The inner spacers 213b are between the nanostructures 212. In some embodiments, the inner spacers 213b may include a dielectric material having higher K value (dielectric constant) than the outer spacers 213a and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), air gap, or a combination thereof.

Each source/drain feature 228 is disposed between two adjacent gate structures and connect (or contact) the nanostructures 212 of the transistors. Each source/drain feature 228 is shared by two adjacent gate structures. In some embodiments, the shared source/drain feature 228 may be also referred to as the common source/drain feature (or common source/drain region) of two adjacent transistors. The source/drain features 228 are formed by the epitaxially-grown materials. In some embodiments, for the N-type transistors, the epitaxially-grown materials may include SiP, SiC, SiPC, SiAs, Si, or a combination thereof.

The source/drain contacts 230f through 230i and 230c extending along the Y-axis are over and contact (or connect) the source/drain features 228. Furthermore, the silicide feature (not shown) is formed between the source/drain contacts 230f through 230i and 230c and the source/drain features 228. The silicide features may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds.

In FIG. 4B, above the active regions 210a and 215a, the connecting feature 310c is formed over and in contact with the source/drain contact 230c. Furthermore, the metal line 320 is formed over and in contact with the connecting feature 310c. Therefore, the source/drain contact 230c is electrically connected to the metal line 320 through the connecting feature 310c. Below the active regions 210a and 215a, the connecting feature 410c is formed under and in contact with the source/drain feature 228 on the left. Therefore, the source/drain contact 230c is electrically connected to the metal line 420 through the connecting feature 410c. In some embodiments, the silicide features (not shown) are formed between the connecting feature 410c and the source/drain feature 228. It should be noted that no connecting feature is formed between the source/drain feature 228 of the active region 215a and the metal line 420.

The IMD 305 and the IMD 405 may include one or more dielectric layers including dielectric materials, such as tetraethylorthosilicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or a combination thereof.

The materials of the source/drain contacts, the connecting features and the metal lines are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

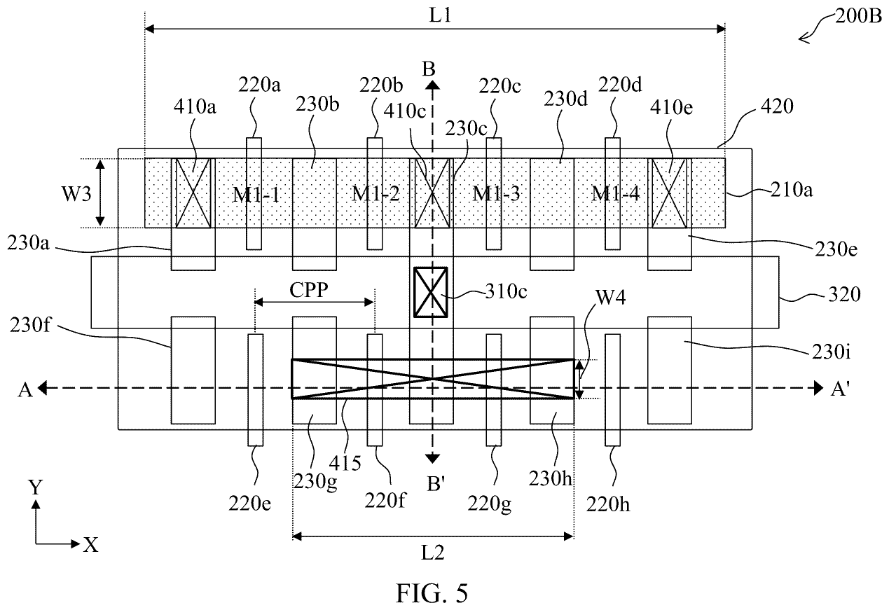

FIG. 5 illustrates an exemplary layout of a semiconductor structure 200B with enhancement interconnects for a power mesh, in accordance with some embodiments of the disclosure. In FIG. 5, the features in the device layer 50 (including transistors), the front-side interconnect structure 300 (including vias and metal lines) and the backside interconnect structure 400 (including vias and metal lines) are shown. The semiconductor structure 200B is formed in the dummy region 175 or the header unit 155 of the WLDV block 120, the IO block 130 or the CNT block 140. In some embodiments, the semiconductor structure 200B is formed in a region of the IC other than the SRAM device 100.

The transistors M1-1 through M1-4 are formed in the active region 210a of the device layer 50 of FIG. 2. Compared with the semiconductor structure 200A of FIG. 3, no active region 215a is formed in the semiconductor structure 200B. In other words, the difference between the semiconductor structure 200A of FIG. 3 and the semiconductor structure 200B of FIG. 5 is that the non-functional active region 215a is removed and a feedthrough via (FTV) 415 is formed in the area where the non-functional active region 215a has been removed.

The FTV 415 extends along the X-axis. In some embodiments, a length L2 of the FTV 415 is less than length L1 and width W4 of the FTV 415 is equal to or less than that of the active region 210a. Furthermore, the FTV 415 overlaps the dummy gate structures 220f and 220g and the source/drain contacts 230g, 230c and 230h. The FTV 415 provides enhancement interconnects between the metal line 320 and the metal line 420, so as to decrease the IR drop in the power mesh for the IC. From a top view, the active region 210a and the FTV 415 are disposed on two opposite sides of the metal line 320.

In some embodiments, the semiconductor structure 200A of FIG. 3 and the semiconductor structure 200B of FIG. 5 are arranged in the same power mesh including the metal lines 320 and 420.

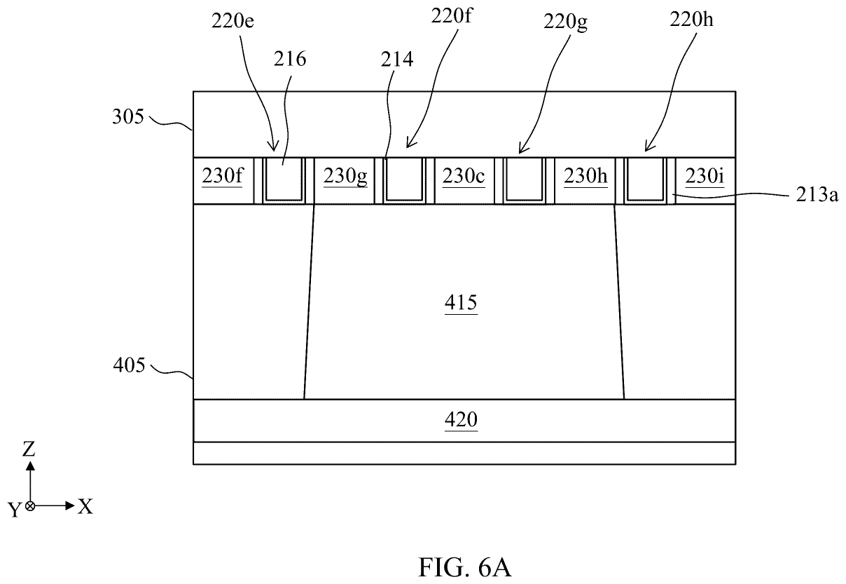

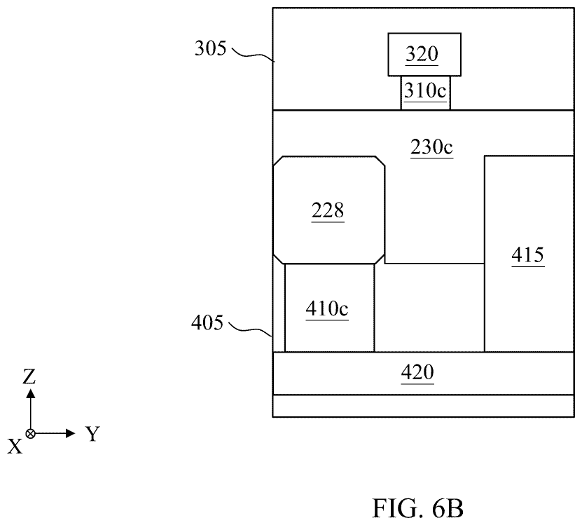

FIG. 6A is a cross section of the semiconductor structure 200B along a line A-A′ in FIG. 5, and FIG. 6B is a cross section of the semiconductor structure 200B along a line B-B′ in FIG. 5, in accordance with some embodiments of the disclosure.

In FIGS. 6A and 6B, the source/drain features 228 under the source/drain contacts 230f through 230i and 230c are removed before the formation of the backside interconnect structure 400. Simultaneously, a portion of the gate structures 220e through 220h is also removed, and only the gate structures 220e through 220h corresponding to the outer spacers 213a are not removed. The source/drain contacts 230g, 230c and 230h are in contact with the FTV 415. Therefore, the source/drain contacts 230g, 230c and 230h are electrically connected to the metal line 420 through the FTV 415. The FTV 415 has lower resistance due to larger area. Furthermore, a depth of the gate structures 220e through 220h is less than that of the gate structures 220a through 220d in the semiconductor structure 200B since the portion of the gate structures 220e through 220h has been removed.

Compared with the semiconductor structure 200A of FIG. 4B, the source/drain contact 230c is further electrically connected to the metal line 420 through the FTV 415 in the semiconductor structure 200B of FIG. 6B. In other words, there are two paths between the metal line 420 and the source/drain contact 230c (or the metal line 320), and a first path is formed by the source/drain feature 228 and the connecting feature 410c and a second path is formed by the FTV 415. In some embodiments, the source/drain contact 230c is further formed in the range between the source/drain feature 228 and the FTV 415. In other words, the bottom surface of source/drain contact 230c in FIG. 6B is lower than the bottom surface of source/drain contact 230c in FIG. 4B. Moreover, when the number of paths between the metal line 420 and the source/drain contact 230c is increased, the equivalent resistance (or impedance) of the parallel paths is decreased. Therefore, by removing the non-functional active region to add the FTV 415, IR performance is improved for the power mesh including the metal lines 320 and 420.

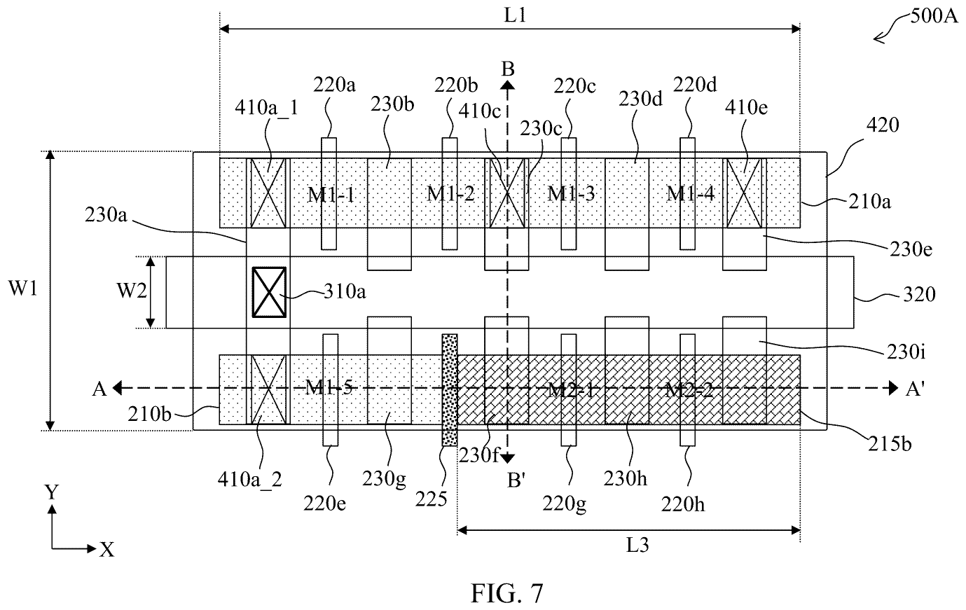

FIG. 7 illustrates an exemplary layout of a semiconductor structure 500A without enhancement interconnects for a power mesh, in accordance with some embodiments of the disclosure. In FIG. 7, the features in the device layer 50 (including transistors), the front-side interconnect structure 300 (including vias and metal lines) and the backside interconnect structure 400 (including vias and metal lines) are shown. The semiconductor structure 500A is formed in the dummy region 175 or the header unit 155 of the WLDV block 120, the IO block 130 or the CNT block 140 in FIG. 1. In some embodiments, the semiconductor structure 500A is formed in a region of the IC other than the SRAM device 100.

The transistors M1-1 through M1-4 are formed in an active region 210a. The transistor M1-5 is formed in an active region 210b, and the transistors M2-1 and M2-2 are formed in an active region 215b. The transistors M1-1 through M1-5 are functional devices capable of performing specific functions of a circuit in the IC, and the active regions 210a and 210b may also be referred to as the functional active regions. The transistors M2-1 and M2-2 are non-functional devices that do not be arranged to perform specific functions in the circuit, and the active region 215b may also be referred to as a non-functional active region. Moreover, the transistors M2-1 and M2-2 are dummy transistors floating in the circuit. Compared with the active region 215a of the semiconductor structure 200A in FIG. 3, the active region 215b of the semiconductor structure 500A has a smaller area, i.e., a length L3 of the active region 215b is less than or equal to 3CPP along the X-axis.

The active regions 210a, 210b and 215b extend along the X-axis and are continuously rectangular in the top view. The configuration of the transistors M1-1 through M1-4 on the active region 210a is the same as the configuration of the transistors M1-1 through M1-4 on the active region 210a in FIG. 3, and description of the transistors M1-1 through M1-4 is omitted herefrom. The gate structure 220e engages the active region 210b to form the transistor M1-5, and the gate structures 220g and 220h engage the active region 215b to form the transistors M2-1 and M2-2. The active region 210b is separated from the active region 215b by an isolation structure 225.

Similar to the semiconductor structure 200A of FIG. 3, the metal line 320 is formed in the lowest metal layer in the front-side interconnect structure 300 of FIG. 2, and the metal line 420 is formed in a metal layer of the backside interconnect structure 400 of FIG. 2 closest to the device layer 50.

In some embodiments, the transistors M1-1 through M1-5 and the transistors M2-1 and M2-2 are N-type transistors, and the metal lines 320 and 420 are the VSS lines. Furthermore, the connecting features 410a_1 and 410a_2, 410c and 410e are disposed between the source regions of the transistors M1-1 through M1-5 and the metal line 420, i.e., the source/drain regions coupled to the connecting features 410a_1 and 410a_2, 410c and 410e are the source features of the N-type transistors.

In some embodiments, the transistors M1-1 through M1-5 and the transistors M2-1 and M2-2 are P-type transistors, and the metal lines 320 and 420 are the VDD lines. Furthermore, the connecting features 410a_1 and 410a_2, 410c and 410e are disposed between the source regions of the transistors M1-1 through M1-5 and the metal line 420, i.e., the source/drain regions coupled to the connecting features 410a_1 and 410a_2, 410c and 410e are the source features of the P-type transistors.

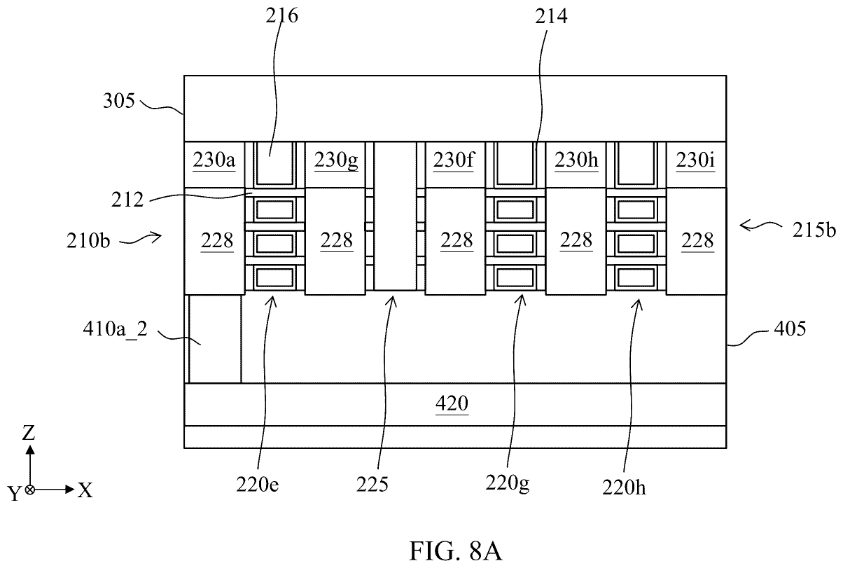

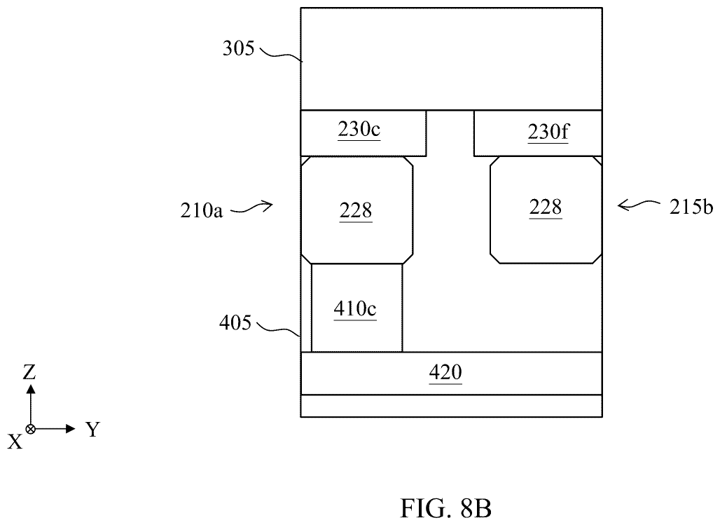

FIG. 8A is a cross section of the semiconductor structure 500A along a line A-A′ in FIG. 7, and FIG. 8B is a cross section of the semiconductor structure 500A along a line B-B′ in FIG. 7, in accordance with some embodiments of the disclosure. In some embodiments, the active region 215b constructed by the nanostructures 212 and the source/drain features 228 retains continuity, and the active region 210b constructed by the nanostructures 212 and the source/drain features 228 retains continuity. The active region 210b is separated from the active region 215b by the isolation structure 225. The isolation structure 225 is a dielectric-base dummy gate.

In some embodiments, the isolation structure 225 includes the gate material formed by the single dielectric layer or multiple layers and selected from a group consisting of SiO₂, SiOC, SiON, SiOCN, Carbon content oxide, Nitrogen content oxide, Carbon and Nitrogen content oxide, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), multiple metal content oxide, or a combination thereof. In some embodiments, the isolation structure 225 may include structures known as continuous poly on diffusion edge (or CPODE), and the CPODE structure may be formed prior to or following a gate replacement process.

As shown in FIGS. 8A and 8B, in the active regions 210a and 210b, the source/drain features 228 corresponding to the source/drain contacts 230a and 230c are electrically connected to the metal line 420 through the connecting features 410a_2 and 410c, respectively. In the active region 215b, the source/drain features 228 corresponding to the source/drain contacts 230f, 230h and 230i are not electrically connected to the metal line 420.

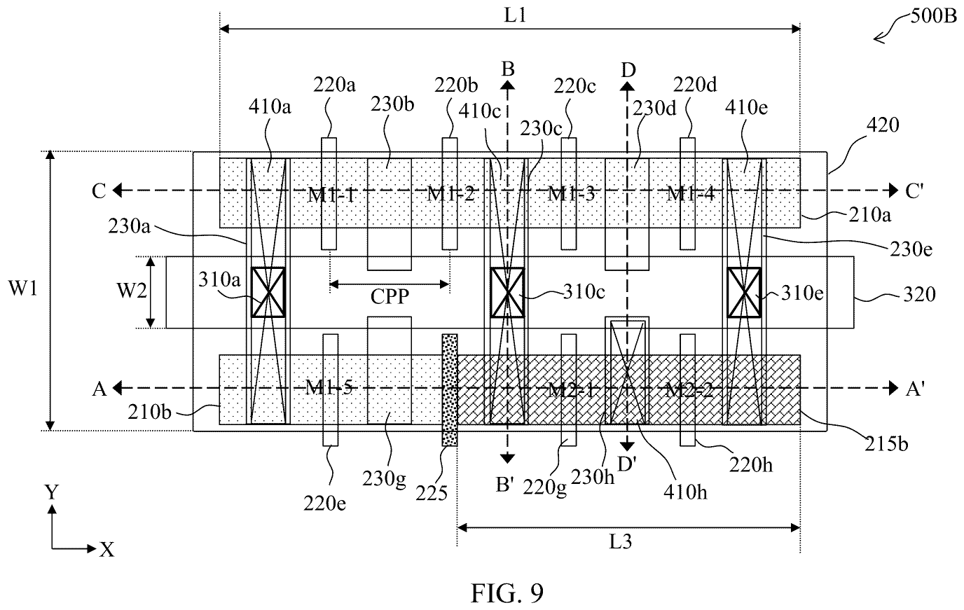

FIG. 9 illustrates an exemplary layout of a semiconductor structure 500B with enhancement interconnects for a power mesh, in accordance with some embodiments of the disclosure. The semiconductor structure 500B is formed in the dummy region 175 or the header unit 155 of the WLDV block 120, the IO block 130 or the CNT block 140 in FIG. 1. In some embodiments, the semiconductor structure 200B is formed in a region of the IC other than the SRAM device 100.

Compared with the active region 215a in the semiconductor structure 200A of FIG. 3, the area of the active region 215b is insufficient to dispose the FTV 415 of FIG. 5. In order to increase the enhancement interconnects, the connecting features 410c and 410e extend to the active region 215b along the Y-axis, thus the source/drain contacts of the active region 215b corresponding to the connecting features 410c and 410e are electrically connected to the metal line 420.

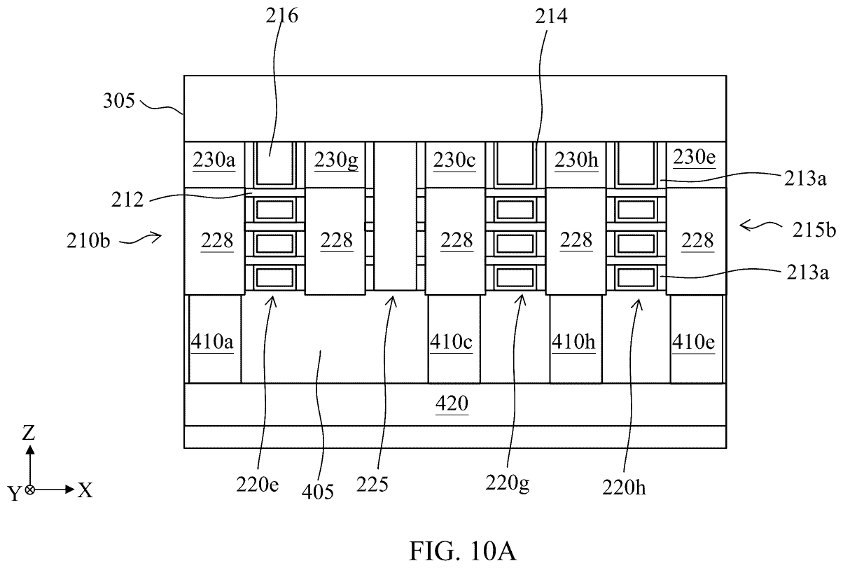

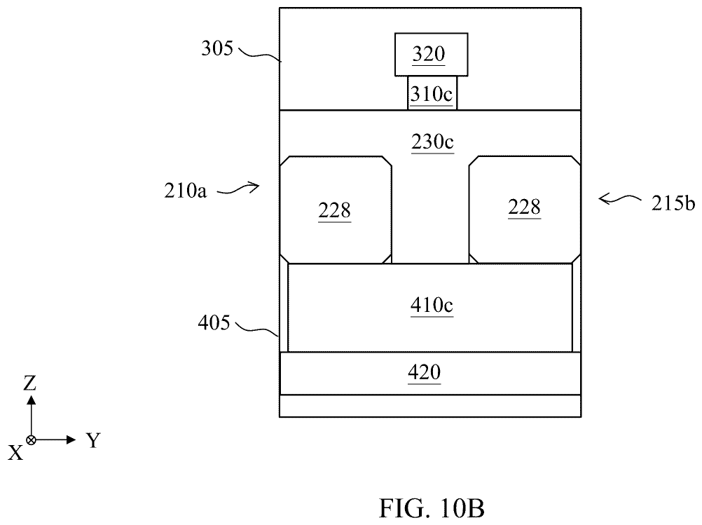

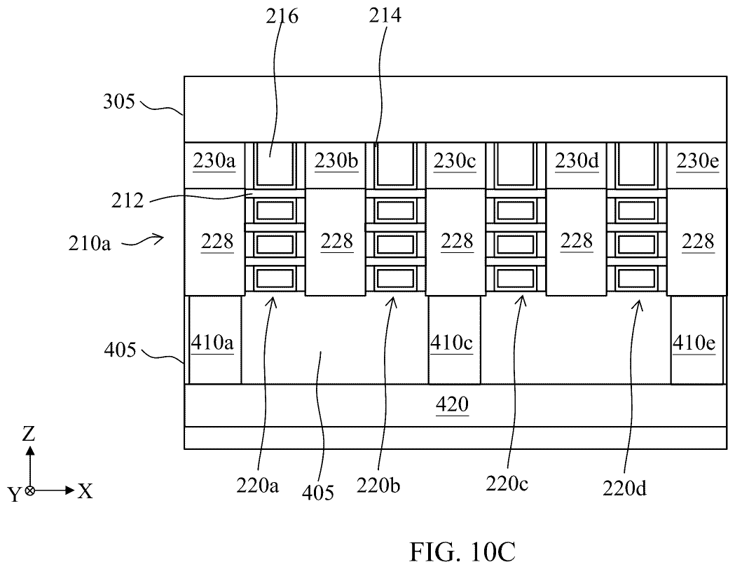

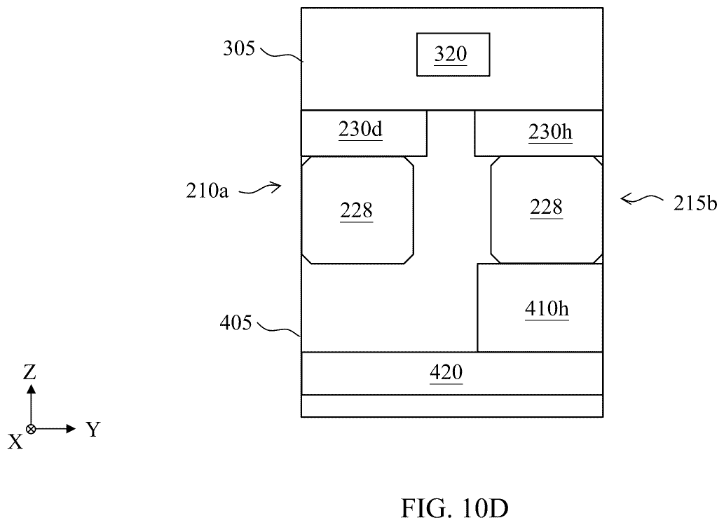

FIGS. 10A through 10D are cross sections of the semiconductor structure 500B along the lines A-A′, B-B′, C-C′ and D-D′ in FIG. 9, respectively, in accordance with some embodiments of the disclosure.

By using the extended connecting features 410c and 410e, the source/drain features 228 of the active region 215b provide additional paths between the metal lines 320 and 420. For example, the metal line 320 is electrically connected to the source/drain contact 230c through the connecting feature 310c, and the source/drain contact 230c is further electrically connected to the metal line 420 through the source/drain features 228 corresponding to the source/drain contact 230c and the connecting feature 410c. In the embodiment, the source/drain contact 230c is further formed in the range sandwiched by the two adjacent source/drain features 228 and is in contact with the connecting feature 410c. As described above, the parallel paths can reduce total resistance of the power mesh including the metal lines 320 and 420, thereby decreasing IR issue for the power mesh.

Furthermore, by using the extended connecting feature 410a, such as the connecting feature 410a_1 that extends to connect the connecting feature 410a_2 in FIG. 7, resistance between the metal line 420 and the source/drain contact 230a is reduced for the power mesh including the metal lines 320 and 420.

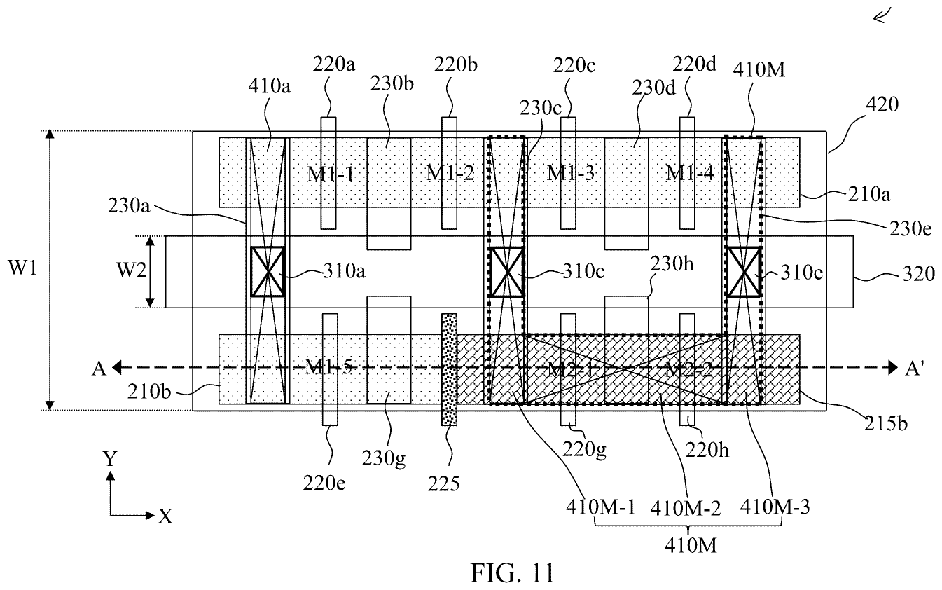

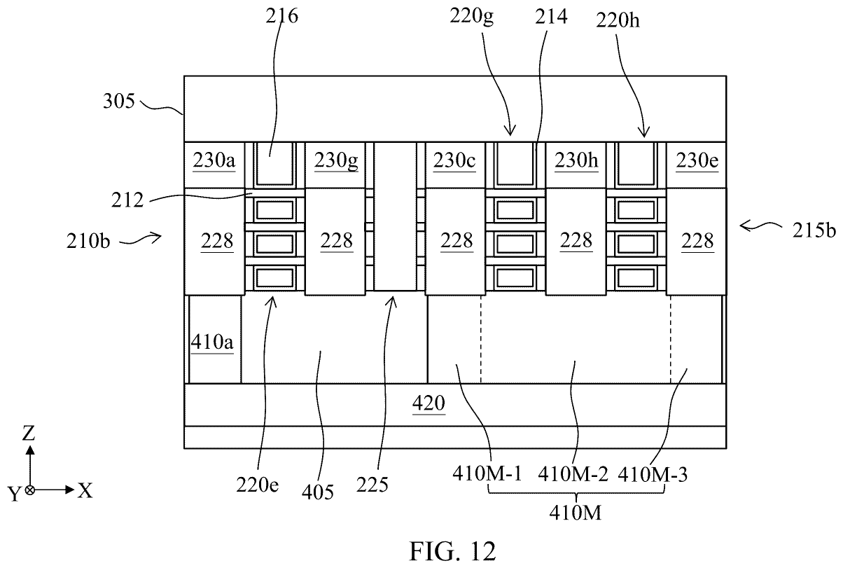

FIG. 11 illustrates an exemplary layout of a semiconductor structure 500C with enhancement interconnects for a power mesh, in accordance with some embodiments of the disclosure. Furthermore, FIG. 12 is a cross section of the semiconductor structure 500C along the lines A-A′ in FIG. 11, in accordance with some embodiments of the disclosure. The semiconductor structure 500C is formed in the dummy region 175 or the header unit 155 of the WLDV block 120, the IO block 130 or the CNT block 140 in FIG. 1. In some embodiments, the semiconductor structure 200C is formed in a region of the IC other than the SRAM device 100.

The semiconductor structure 500C of FIG. 11 is similar to the semiconductor structure 500B of FIG. 9. The difference between the semiconductor structure 500C and the semiconductor structure 500B is that the semiconductor structure 500C of FIG. 11 includes a merged connecting feature 410M.

The merged connecting feature 410M is formed by the connecting features 410M-1, 410M-2 and 410M-3. The connecting features 410M-1 and 410M-3 extending along the Y-axis are similar to the connecting features 410c and 410e of the semiconductor structure 500B in FIG. 9, respectively. The connecting feature 410M-2 extending along the X-axis is disposed between and in contact with the connecting features 410M-1 and 410M-3. Furthermore, a width of the connecting feature 410M-2 is equal to a width of the active region 215b in the Y-axis. In the embodiment, the merged connecting feature 410M can provide larger area contacting the metal line 420, thereby decreasing total resistance of the power mesh of the metal lines 320 and 420 and improving IR performance.

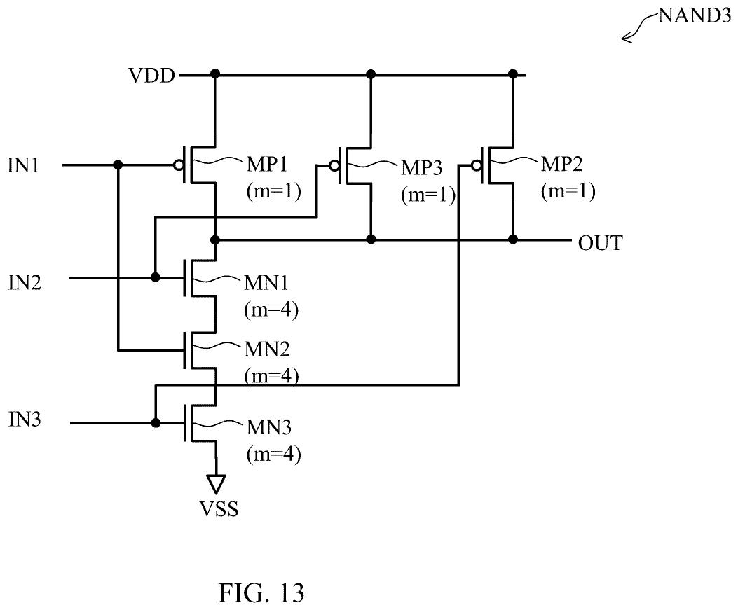

FIG. 13 is a circuit diagram of a logic cell NAND3, in accordance with some embodiments of the disclosure. The logic cell NAND3 is capable of performing an NAND logic operation on three input signals IN1, IN2 and IN3 to provide an output signal OUT. The logic cell NAND3 includes three P-type transistors MP1, MP2 and MP3 and three N-type transistors MN1, MN2 and MN3. The P-type transistors MP1, MP2 and MP3 are connected in parallel between the VDD line and the N-type transistor MN1, and the N-type transistors MN1, MN2 and MN3 are connected in series between the P-type transistor MP1 and a VSS line.

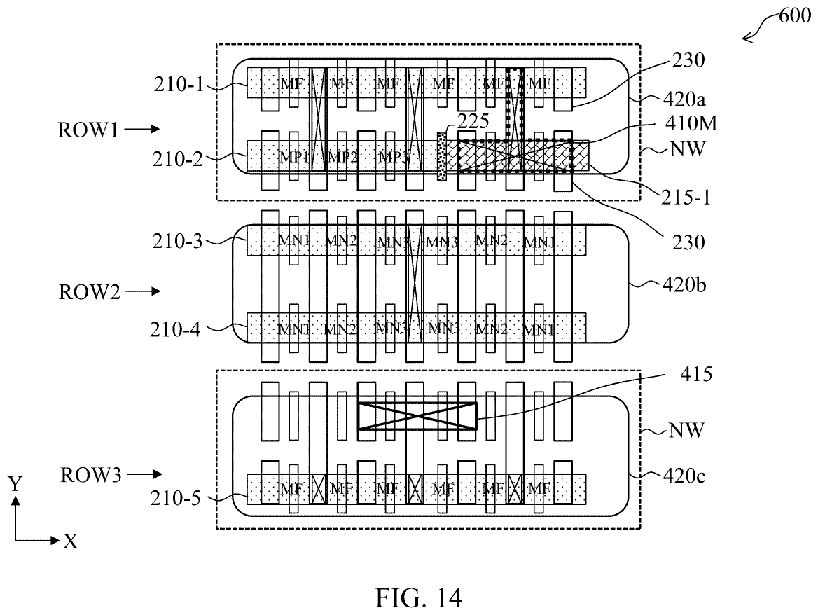

FIG. 14 illustrates an exemplary layout of a semiconductor structure 600 of the logic cell NAND3 in FIG. 13, in accordance with some embodiments of the disclosure. In the semiconductor structure 600 with enhancement interconnects for VDD mesh, the active regions 210-1 and 210-2 and the active region 215-1 are arranged in the row ROW1 corresponding to the metal line 420a. Moreover, the active regions 210-3 and 210-4 are arranged in the row ROW2 corresponding to the metal line 420b, and the active region 210-5 is arranged in the row ROW3 corresponding to the metal line 420c. The active regions 210-1 and 210-2 of the row ROW1 and the active region 210-5 of the row ROW3 are formed in the N-type well regions NW. Therefore, the transistors formed in the rows ROW1 and ROW3 are P-type transistors, and the transistors formed in the row ROW2 are N-type. The metal lines 420a through 420c are formed in a metal layer of the backside interconnect structure 400 closest to the device layer 50 of FIG. 2. The metal lines 420a and 420c are the VDD lines, and the metal line 420b is the VSS line.

The active regions 210-1 through 210-5 are functional active regions, and active region 215-1 is a non-functional active region. In the row ROW1, the active region 210-2 is separated from the active region 215-1 by the isolation structure 225. The P-type transistors MP1 through MP3 are formed in the active region 210-2. The N-type transistors MN1 through MN4 are formed in the active regions 210-3 and 210-4. The P-type transistors MF of the circuit other than the logic cell NAND3 are formed in the active regions 210-1 and 210-5.

In the semiconductor structure 600, the configuration of the front-side interconnect structure 300 is omitted. A merged connecting feature 410M is formed in the row ROW1, so as to provide larger area contacting the metal line 420a. Furthermore, a FTV 415 extending along the X-axis is formed in the row ROW3 and between the active regions 210-4 and 210-5, so as to provide larger area contacting the metal line 420c. Through the VDD interconnect configuration (not shown) in the front-side interconnect structure 300, IR performance is improved for the VDD mesh including the metal lines 420a and 420c because of the merged connecting feature 410M and the FTV 415. As described above, the FTV 415 is formed by removing the larger non-functional active region, and the extended or merged connecting feature 410 is formed in the smaller non-functional active region.

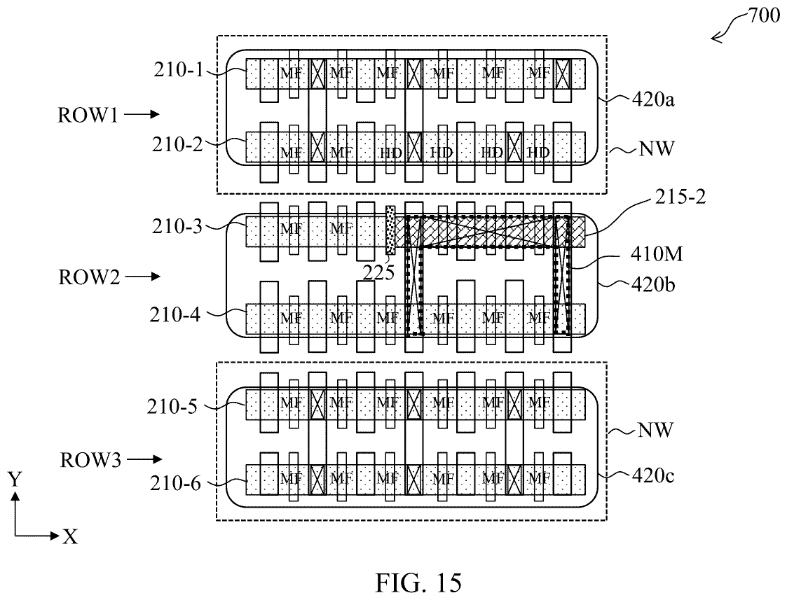

FIG. 15 illustrates an exemplary layout of a semiconductor structure 700 with enhancement interconnects for VSS mesh, in accordance with some embodiments of the disclosure.

In the semiconductor structure 700, the active regions 210-1 and 210-2 are arranged in the row ROW1 corresponding to the metal line 420a, the active regions 210-3 and 210-4 and the active region 215-2 are arranged in the row ROW2 corresponding to the metal line 420b, and the active regions 210-5 and 210-6 are arranged in the row ROW3 corresponding to the metal line 420c. The active regions 210-1 and 210-2 of the row ROW1 and the active regions 210-5 and 210-6 of the row ROW3 are formed in the N-type well regions NW. Therefore, the transistors formed in the rows ROW1 and ROW3 are the P-type transistors, and the transistors formed in the row ROW2 are the N-type transistors. The metal lines 420a through 420c are formed in a metal layer of the backside interconnect structure 400 closest to the device layer 50 of FIG. 2. The metal lines 420a and 420c are the VDD lines, and the metal line 420b is the VSS line.

The active regions 210-1 through 210-6 are functional active regions, and the active region 215-2 is a non-functional active region. In the row ROW2, the active region 210-3 is separated from the active region 215-2 by the isolation structure 225. In the semiconductor structure 700, the transistors HD are configured to perform the operations of the header unit 155 of FIG. 1, and the transistors MF are configured to perform the operations other than the header unit 155. Because the transistors HD are scattered, the non-functional active region 215-2 is disposed next to the transistors HD. If the non-functional active region 215-2 has a greater area enough to dispose the FTV 415 of FIG. 5, the non-functional active region 215-2 is removed, and the FTV 415 is formed over the metal line 420b. If the non-functional active region 215-2 has a smaller area where the FTV 415 cannot be disposed, a merged connecting feature 410M or an extended connecting feature (e.g., the connecting feature 410c of FIG. 9) is formed in the non-functional active region 215-2. Thus, IR performance is improved for the VSS mesh including the metal line 420b because of the merged connecting feature 410M.

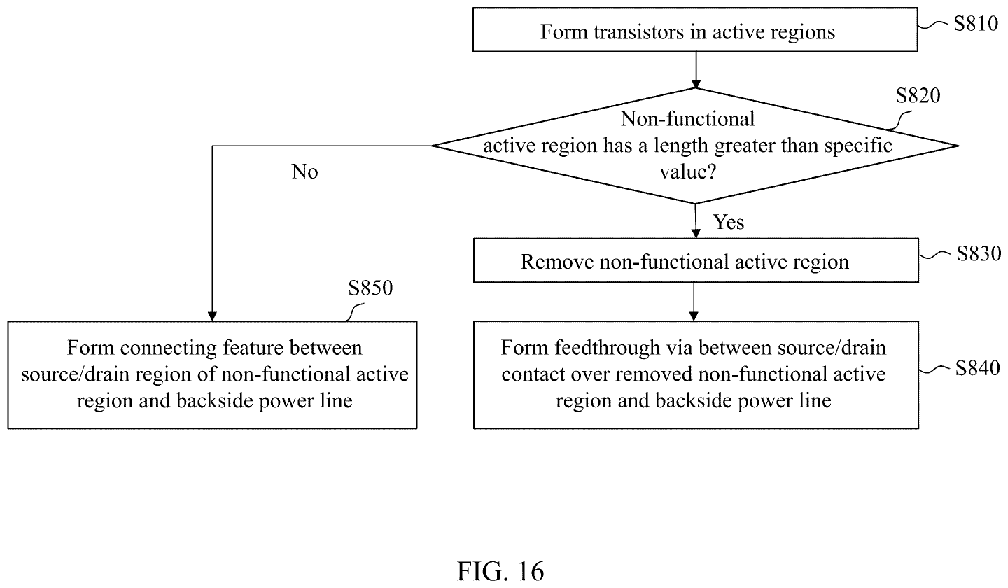

FIG. 16 shows a method for manufacturing a semiconductor structure, in accordance with some embodiments of the disclosure, and the semiconductor structure has enhancement interconnects for power mesh. It should be understood that the embodiment method shown in FIG. 16 is merely an example of many possible embodiments. One of ordinary skill in the art could recognize many variations, alternatives, and modifications. For example, various operations as illustrated in FIG. 16 can be added, removed, replaced, rearranged, or repeated.

In operation S810, the transistors are formed in the active regions including the functional active regions and at least one non-functional active regions. In the same row, the functional active region and the non-functional active region are separated from each other by the isolation structure 225. Furthermore, the gates of transistors in the non-functional active regions are floating.

In operation S820, it is determined whether length of the non-functional active region (e.g., the active region 215a of FIG. 3 or 215b of FIG. 7) exceeds a specific value. For example, it is determined whether the length L3 of the non-functional active region exceeds 3CPP (contacted poly pitch), i.e., 3 times the transistor gate pitch.

If the length L3 of the non-functional active region exceeds the specific value, the non-functional active region is removed in operation S830. Next, in operation S840, a feedthrough via (e.g., the FTV 415 of FIG. 5) is formed between the multiple source/drain contacts over the removed non-functional active region and the power line of the backside interconnect structure 400. For example, the FTV 415 is formed between the source/drain contacts 230g, 230c and 230h and the metal line 420, as shown in FIG. 6A.

If the length L3 of the non-functional active region does not exceed the specific value, at least a connecting feature is formed between the source/drain region of the non-functional active region and the power line of the backside interconnect structure 400 in operation S850. Furthermore, the connecting feature further extends to the adjacent functional active region over the power line. For example, the connecting feature 410c is formed between the source/drain feature 228 of the active region 215b and the metal line 420, and further extends to the source/drain feature 228 of the active region 210a, as shown in FIGS. 9 and 10B. In some embodiments, the connecting feature may be a merged connecting feature 410M, as shown in FIGS. 11, 14 and 15.

By arranging the backside connecting feature between the source/drain region of the non-functional active region and the power line of the backside interconnect structure or replacing the non-functional active region with the FTV, more interconnects are provided for the power line under the non-functional active region, thereby decreasing resistance and improving IR drop for the power mesh of IC.

According to some embodiments, a semiconductor structure is provided. The semiconductor structure includes a plurality of transistors formed in an active region of a device layer, a first power line disposed on a front side of the device layer and extending along a first axis, a first connecting feature disposed on a source/drain region of the transistors and extending along a second axis perpendicular to the first axis, a second power line disposed on a back side of the device layer and extending along the first axis, and a feedthrough via formed on and in contact with the second power line. The active region extends along the first axis. The active region and the feedthrough via are disposed on two opposite sides of the first power line from a top view. The second power line is electrically connected to the source/drain region of the transistors through the feedthrough via and the first connecting feature.

According to some embodiments, a semiconductor structure is provided. The semiconductor structure includes a plurality of first transistors formed in a first active region of a device layer, a plurality of second transistors formed in a second active region of the device layer, a first power line disposed on a front side of the device layer and extending along a first axis, a first connecting feature, a second power line, and a first backside connecting feature. The first active region extends along the first axis. The second active region extends along the first axis, and gates of the second transistors are floating. The first active region and the second active region are disposed on two opposite side of the first power line from a top view. The first connecting feature extends from a first source/drain region of the first transistors to a second source/drain region of the second transistors along a second axis perpendicular to the first axis. The second power line is disposed on a back side of the device layer and extends along the first axis. The first backside connecting feature extends from the first source/drain region to the second source/drain region along the second axis on the back side of the device layer. The second power line is electrically connected to the first source/drain region and the second source/drain region through the first backside connecting feature.

According to some embodiments, a method for manufacturing a semiconductor structure is provided. A plurality of transistors are formed in a plurality of active regions. It is determined whether a non-functional active region of the active regions has a length greater than a specific value. The non-functional active region is removed when the length of the non-functional active region is greater than the specific value. A feedthrough via is formed between a backside power line and a source/drain contact over the removed non-functional active region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a plurality of transistors formed in an active region of a device layer, wherein the active region extends in a first direction;
a first power line disposed on a front side of the device layer and extending in the first direction;
a first connecting feature disposed on a source/drain region of the transistors and extending in a second direction perpendicular to the first direction;
a second power line disposed on a back side of the device layer and extending in the first direction; and
a feedthrough via formed on and in contact with the second power line, wherein the active region and the feedthrough via are disposed on two opposite sides of the first power line from a top view,
wherein the second power line is electrically connected to the source/drain region of the transistors through the feedthrough via and the first connecting feature.

2. The semiconductor structure of claim 1, further comprising:
a second connecting feature disposed on the back side of the device layer and between the source/drain region of the transistors and the second power line,
wherein the second power line is further electrically connected to the source/drain region of the transistors through the second connecting feature.

3. The semiconductor structure of claim 1, further comprising:
a third connecting feature disposed on the front side of the device layer and between the first connecting feature and the first power line,
wherein the first power line is electrically connected to the source/drain region of the transistors through the third connecting feature and the first connecting feature.

4. The semiconductor structure of claim 1, wherein a width of the feedthrough via is equal to or less than a width of the active region in the second direction.

5. The semiconductor structure of claim 1, wherein a length of the feedthrough via is less than a length of the active region in the first direction.

6. The semiconductor structure of claim 1, wherein the feedthrough via overlaps a plurality of dummy gate structures extending in the second direction from a top view.

7. The semiconductor structure of claim 6, wherein a depth of the dummy gate structures is less than a depth of a gate structure of the transistors.

8. The semiconductor structure of claim 1, wherein the first power line and the second power line correspond to a power mesh, and the second power line is wider than the first power line.

9. A semiconductor structure, comprising:
a plurality of first transistors formed in a first active region of a device layer, wherein the first active region extends in a first direction;
a plurality of second transistors formed in a second active region of the device layer, wherein the second active region extends in the first direction, and gates of the second transistors are floating;
a first power line disposed on a front side of the device layer and extending in the first direction, wherein the first active region and the second active region are disposed on two opposite side of the first power line from a top view;
a first connecting feature extending from a first source/drain region of the first transistors to a second source/drain region of the second transistors along a second direction perpendicular to the first direction;
a second power line disposed on a back side of the device layer and extending in the first direction; and
a first backside connecting feature extending from the first source/drain region to the second source/drain region along the second direction on the back side of the device layer,
wherein the second power line is electrically connected to the first source/drain region and the second source/drain region through the first backside connecting feature.

10. The semiconductor structure of claim 9, further comprising:
a second connecting feature disposed on the front side of the device layer and between the first connecting feature and the first power line,
wherein the first power line is electrically connected to the first source/drain region and the second source/drain region through the first connecting feature and the second connecting feature.

11. The semiconductor structure of claim 9, further comprising:
at least one third transistor formed in a third active region of the device layer, wherein the third active region extends in the first direction, and the second active region and the third active region are separated by an isolation structure; and
a second backside connecting feature extending from a third source/drain region of the first transistors to a fourth source/drain region of the third transistor along the second direction on the back side of the device layer,
wherein the second power line is electrically connected to the third source/drain region and the fourth source/drain region through the second backside connecting feature.

12. The semiconductor structure of claim 11, wherein the second power line overlaps the first, second and third active regions and the first power line from a top view.

13. The semiconductor structure of claim 9, wherein a length of the second active region is less than or equal to 3 times gate pitch of the second transistors.

14. The semiconductor structure of claim 9, further comprising:
a third backside connecting feature extending from a fifth source/drain region of the first transistors to a sixth source/drain region of the second transistors along the second direction on the back side of the device layer; and
a fourth backside connecting feature extending from the second source/drain region to the sixth source/drain region along the first direction on the back side of the device layer,
wherein the first, third and fourth backside connecting features from a merged backside connecting feature.

15. The semiconductor structure of claim 14, wherein a width of the fourth backside connecting feature is equal to a width of the second active region in the second direction.

16. The semiconductor structure of claim 9, wherein the first power line and the second power line correspond to a power mesh, and the second power line is wider than the first power line.

17. A method for manufacturing a semiconductor structure, comprising:
forming a plurality of transistors in a plurality of active regions;
determining whether a non-functional active region of the active regions has a length greater than a specific value;
removing the non-functional active region when the length of the non-functional active region is greater than the specific value; and
forming a feedthrough via between a backside power line and a source/drain contact over the removed non-functional active region.

18. The method of claim 17, further comprising:
forming a backside connecting feature between the backside power line and a source/drain region of the transistors in the non-functional active region when the length of the non-functional active region is not greater than the specific value.

19. The method of claim 17, wherein the specific value is equal to 3 times a gate pitch of the transistors.

20. The method of claim 17, wherein the non-functional active region is separated from a functional active region of the active regions by an isolation structure.
